(19) United States
(12) Patent Application Publication
(10) Pub. No.: US 2007/0056768 A1
(43) Pub. Date: Mar. 15, 2007

(54) Apparatus for minimizing electromagnetic interferences

(76) Inventors: Chang-Cheng Hsieh, Tao Yuan City (TW); Kang Wu, Kuei Shan Hsiang (TW)

Correspondence Address: RABIN & BERDO, P.C., Suite 500, 1101 14 Street, N.W., Washington, DC, 20005, US

(21) Appl. No.: 11/443,298

(22) Filed: May 31, 2006

(30) Foreign Application Priority Data
Sep. 9, 2005 (TW) 94131208

(51) Int. Cl. H05K 9/00

(52) U.S. Cl. 174/350

(57) ABSTRACT

An apparatus for minimizing electromagnetic interferences, comprising a top shielding on which a trench with a predetermined depth is formed; an elastomer disposed in the trench with a predetermined thickness greater than the predetermined depth of the trench; and a conductive film, with at least one side of which is anchored to the top shielding and partially covers the trench, so that the film can be in contact with a high-frequency device to direct the RF noise to the grounding terminal of a motherboard to minimize electromagnetic interferences of the electronic devices.

### RELATED APPLICATIONS

The present application is based on, and claims priority from, Taiwan Application Serial Number 94131208, filed Sep. 9, 2005, the disclosure of which is hereby incorporated by reference herein in its entirety.

### BACKGROUND

1. Field of Invention

The present invention relates to consumer electronic products. More particularly, the present invention relates to an apparatus for minimizing electromagnetic interferences in an electronic product.

2. Description of Related Art

With rapid development in technology and increased consumer requirements for electronic products, manufacturers aim to provide more compact and stable electronic products with higher performance. However, electronic products are becoming more complex and the density of circuit devices is unavoidably increasing thereby causing more interference between internal electronic devices. Among interferences, manufacturers consider electromagnetic interferences and RF noise to be the most serious. As the market for electronic products becomes more competitive, manufacturers continue to search for simple and effective solutions to reduce electromagnetic interferences in order to shorten the time to market.

Electromagnetic interference (EMI) comes in two few forms, conducted and radiated. Conducted EMI, with lower frequencies (<30 MHz), usually transmits unwanted noise from a power line through which electromagnetic interferences generated by different devices (connected to the same power supply) interfere with one another. Radiated EMI, with higher frequencies (>30 MHz), however, usually transmits noise through free space without any transmitting mediums and is generally reduced through shielding or grounding. Many electronic products contain high-frequency devices, such as RAM (Random Access Memory) or CPUs (Central Processing Unit) that would cause a radiation source to be formed in a loop during high frequency switching. If the product is grounded improperly, a slot or casing over the high frequency devices becomes a monotonic antenna through which radio frequencies are radiated into space and may cause interferences to other devices or circuits.

Products are typically designed with EMI protection from either radiated EMI or conducted EMI, or both. The position of the devices and the circuit arrangement should also be taken into consideration so that the circuits or devices do not interfere with each other during operation. The product or equipment itself should not be a radiation source either. The primary problem with the occurrence of EMI is disruption or reduction of electronic device performance. In addition to improving the circuit arrangement, any kind of shielding material, for example, a conductive gasket, can be used to absorb or obstruct electromagnetic interferences.

The conductive gasket that has been widely used in electronic products such as personal computers, servers and mobile phones is an electrically conductive foam strip (about 0.5-0.8 mm thick) wrapped in electrically conductive fabrics and acts as a contact between two metals. Electrically conductive gaskets with various shapes and sizes offer excellent shielding properties. However, there are still some usage limitations, i.e., the conductive gasket may not be suitable for compact products since those products have less space for EMI protection devices. For example, it has been found that the keyboard side of the laptop computer sometimes fluctuates a little bit and is unstable if a thicker conductive gasket is disposed within a gap less than 0.5 mm that is usually reserved for the purpose of assembling. Even if the gaskets are designed to be relatively thin, the costs are still higher for such a design. Besides, with long operation times at high temperature, particles or fragments resulting from chemical changes of the electrically conductive fabrics or gaskets would contaminate the internal devices, thereby damaging critical electronic components.

Therefore, it would be advantageous to provide a simple and practical design for minimizing electromagnetic interferences in electronic products.

### SUMMARY

It is therefore an objective of the present invention to provide simple and practical apparatuses for minimizing electromagnetic interferences in electronic products, in order to solve the problem that the conventional gasket is too thick to dispose within the smaller electronic products, and that the particles or fragments resulting from chemical changes of the electrically conductive fabrics or gaskets would contaminate the internal devices and degrade the performance of the electronics.

In one aspect of the present invention, the apparatus comprises a top shielding on which a trench with a predetermined depth is formed; an elastomer disposed in the trench with a predetermined thickness greater than the predetermined depth of the trench; and a conductive film, of which at least one side is anchored to the top shielding and partially covers the trench so that the film can be in contact with a high-frequency device that directs the RF noise to a motherboard grounding terminal to minimize electromagnetic interferences of the electronic devices.

In another aspect of the present invention, electronic equipment is provided to minimize electromagnetic interferences. The electronic equipment includes a casing; a motherboard disposed within the casing; a high-frequency device disposed on the motherboard in indirect contact with a top shielding on which a trench with a predetermined depth is formed; an elastomer disposed in the trench with a predetermined thickness greater than the predetermined depth of the trench; and a conductive film, of which at least one side is anchored to the top shielding and partially covers the trench so that the film can be in contact with a high-frequency device and be able to direct RF noise to a motherboard grounding terminal, thus minimizing electromagnetic interferences of the electronic devices. Other aspects and advantages of the invention are more fully apparent from the ensuing disclosure, appended claims and drawings.

### BRIEF DESCRIPTION OF THE DRAWINGS

These and other features, aspects and advantages of the present invention become better understood with regard to the following description, appended claims and accompanying drawings, where:

FIG. 1 is an exploded view of an apparatus for minimizing electromagnetic interferences and other related components in accordance with one embodiment of the present invention;

FIG. 2 is a cross-sectional side view taken along line 2-2 of FIG. 1.

### DESCRIPTION OF THE PREFERRED EMBODIMENTS

Reference is now made in detail to the present preferred embodiments of the invention, examples of which are illustrated in the accompanying drawings. Wherever possible, the same reference numbers are used in the drawings and the description to refer to the same or like parts.

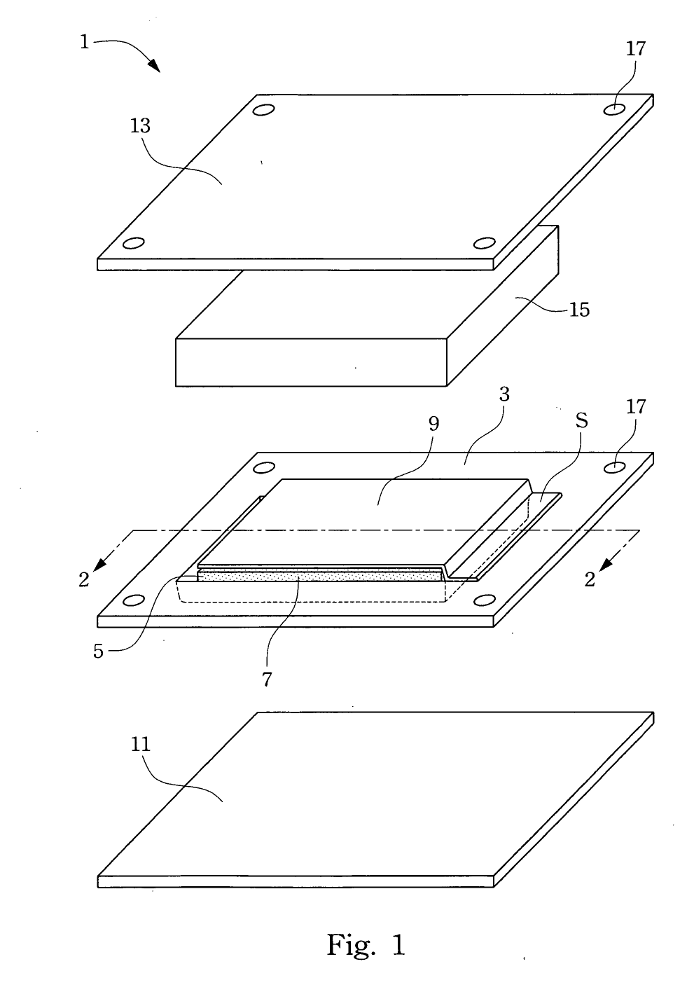

FIG. 1 shows an exploded view of an apparatus that minimizes electromagnetic interferences and other related components in accordance with one embodiment of the present invention. FIG. 1 illustrates an apparatus 1 including: a top shielding 3 on which a trench 5 with a predetermined depth “d” is formed; an elastomer 7 disposed in the trench 5 with a predetermined thickness “t” greater than the predetermined depth “d” of the trench; and a conductive film 9, of which at least one side “s” is anchored on the top shielding 3 and partially covers the trench 5, wherein the elastomer 7 within the trench 5 presses the conductive film 9 against a high-frequency device 15 with a predetermined contact pressure.

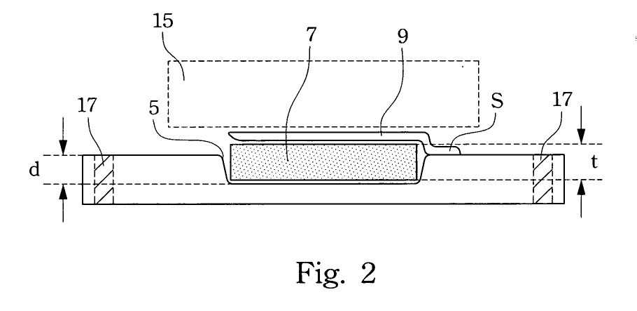

FIG. 2 is a cross-sectional side view taken along line 2-2 of FIG. 1. FIG. 2 clearly illustrates relative positions of the top shielding 3, trench 5, elastomer 7 and conductive film 9.

According to one embodiment of the present invention, the top shielding 3 of the apparatus 1 typically consists of metals, such as aluminum, aluminum-magnesium alloy or other conductive materials. Since electromagnetic interferences primarily comes from high-frequency devices such as CPUs, RAMs, amplifiers or integrated chips, the top shielding 3 in the electronic equipment is preferably disposed at one side of the high-frequency device 15. In this embodiment, for example, the top shielding 3 is located below the high-frequency device 15. The top shielding 3 is capable of shielding and directing large amounts of RF noise from high-frequency devices to grounding terminals.

On the top shielding 3 at least one trench 5 with a predetermined depth “d” is formed by punching, stamping or any other suitable methods. The surface of the trench 5 is closely related to the structural strength of the top shielding 3 and thus should be taken into account. The predetermined depth “d” should not affect the disposal of those devices below. Generally, the surface area of the trench 5 varies and depends on the contact pressure between the conductive film 9 and the high-frequency device 15. The present inventor has found that the predetermined contact pressure of at least 100 mg/cm² is needed between the conductive film and the high-frequency device. Thus the predetermined contact pressure should be greater than about 100 mg/cm². If the contact pressure between the conductive film 9 and the high-frequency device 15 is lower than 100 mg/cm², the force exerted on the surface area of the conductive film 9 could be increased to enhance the overall contact pressure. The surface area of the trench 5 should be inversely proportional to the contact pressure between the conductive film 9 and the high-frequency device 15 since the conductive film 9 needs at least partial covering of the trench 5. It should be noted that the above strip-like trench is one of the preferred embodiments of the present invention and should not be considered as a limitation to the present invention. Any shape can be applied so long as the conductive film 9 and the high-frequency device 15 are in effective contact with one another.

The elastomer 7 is fixed on the bottom of the trench 5 with an adhesive. The elastomer 7 is preferably a low compression ratio material, such as foamed sponge, PU foam or some other suitable material. In one embodiment of the present invention, the predetermined thickness “t” of the elastomer 7 is greater than the predetermined depth “d” of the trench 5. Specifically, the top of the elastomer 7 is higher than that of the top shielding 3 when the elastomer 7 is not being compressed. The larger the gap between the top shielding 3 and the high-frequency device 15, the thicker the elastomer 7 to be used, so that the high-frequency device 15 can be in proper contact with the conductive film 9. The thickness “t” of the elastomer 7 is directly proportional to the gap between the bottom of the trench 5 and the surface of the high-frequency device 15. As mentioned above, the surface area of the elastomer 7 is slightly less than that of the trench 5 such that the elastomer 7 is properly within the trench 5. The elastomer 7 may be replaced by other devices or mechanisms, such as a flat spring or spring. However, it is required that the conductive film 9 is pressed against the high-frequency device 15 by the elastomer 7.

FIG. 2 shows the conductive film 9 above the elastomer 7 with one side “s” anchored to the top shielding 3 and the conductive film 9 partially covering the trench 5. The term “partially covering” means some spaces are left at latitudinal sides of the trench 5, and only one longitudinal side of the conductive film 9 is anchored on the top shielding 3. However, the trench 5 can be fully covered by the conductive film 9 if the high-frequency 15 devices are in proper contact.

The conductive film 9 has a predetermined surface area, which can be varied depending on the electromagnetic interferences that is to be reduced. In one embodiment of the invention, the conductive film 9 can be either a high conductivity material or a low-k material, for example, copper. The suitable material for conductive film 9 should be stable in the conditions of high operational temperature or large temperature difference. Any other suitable material, such as aluminum or proper composite materials, can also be used. Brittle material and the material changed under high operational temperature should be avoided using for the conductive film 9.

Proper grounding is essential to prevent damage caused by electromagnetic interferences. In one embodiment of the present invention, the conductive film 9 is in indirect contact with the high-frequency device 15 when a conductive or a shielding component is disposed between the conductive film 9 and the high-frequency device 15. For example, there could be a grounding device between the conductive film 9 and the high-frequency device 15. The grounding device preferably includes a grounding port (not shown), through which a grounding terminal such as the casing of an electronic product is connected. The term “grounding” described herein refers to those conductive connections, either intentionally or accidentally. The grounding device itself could be any device (e.g., extended slot) or the casing of the electronic product. By using the grounding device, electromagnetic interferences or RF noise resulting from the high-frequency device can be directed to the grounding terminal via the grounding port, or to the motherboard with a proper grounding via the top shielding 3 so that the high-frequency device is at the same potential as the ground, thereby minimizing the electromagnetic interferences of the electronic products. In one embodiment of the present invention, the top shielding 3 provides a number of screws 17 through which the RF noise can be directed to a motherboard with a proper grounding. It should be apparent to those of ordinary skill in the art that other suitable grounding measures can also be applied to the present invention.

The present apparatus is desirable electronic equipment with high-frequency devices therein, such as laptop computers or computer peripherals, mainframe computers, mobile phones, PDAs, or medical equipment. High-frequency devices, such as a CPU, integrated chips or communication devices, are usually disposed on the motherboard. By having the apparatus on one side of the high-frequency device, the RF noise is directed from the conductive film, via the top shielding, to a motherboard with a proper grounding or a grounding device for minimizing electromagnetic interferences of the electronic devices.

It will be apparent to those skilled in the art that various modifications and variations can be made to the structure of the present invention without departing from the scope or spirit of the invention. Accordingly, while the present invention has been disclosed with specific embodiments thereof, it should be understood that other embodiments may fall within the spirit and scope of the invention, as defined by the following claims.

1. An apparatus for minimizing electromagnetic interferences, comprising:
a top shielding on which a trench with a predetermined depth is formed;
an elastomer disposed within the trench with a predetermined thickness greater than the predetermined depth of the trench; and
an electrical conductive film, having at least one side anchored on the top shielding, the electrical conductive film being Pressed by the elastomer and covering the trench so as to be electrically connected with a high-frequency device with a predetermined contact pressure.

2. The apparatus as claimed in claim 1, wherein the top shielding comprises at least one made of aluminum, aluminum-magnesium alloy or other conductive materials.

3. The apparatus as claimed in claim 1, wherein the elastomer includes a low compression ratio material

4. The apparatus as claimed in claim 3, wherein the low compression ratio material is a foamed sponge or PU foam.

5. The apparatus as claimed in claim 1, wherein the surface area of the elastomer is less than that of the trench and is sufficient to press the electrical conductive film to contact the high-frequency device with the predetermined contact pressure.

6. The apparatus as claimed in claim 1, wherein the electrical conductive film is in indirect contact with the high-frequency device via a grounding device.

7. The apparatus as claimed in claim 6, wherein the grounding device further comprises a grounding port, which is connected to a grounding terminal, so that RF noise from high-frequency devices is directed from the grounding port to the grounding terminal.

8. The apparatus as claimed in claim 1, wherein the electrical conductive film comprises of a high conductivity material.

9. The apparatus as claimed in claim 8, wherein the high conductivity material comprises copper.

10. The apparatus as claimed in claim 1, wherein the predetermined contact pressure between the electrical conductive film and the high-frequency device is greater than about 100 mg/cm².

11. The apparatus as claimed in claim 10, wherein the electrical conductive film partially covers the trench.

12. The apparatus as claimed in claim 1, wherein the electrical conductive film partially covers the trench.

13. An electronic equipment for minimizing electromagnetic interferences, comprising a casing, a motherboard disposed in the casing, a high-frequency device disposed on the motherboard and indirectly connected with a top shielding, characterized by:
the top shielding on which a trench with a predetermined depth is formed;
an elastomer disposed within the trench with a predetermined thickness greater than the predetermined depth of the trench; and
an electrical conductive film, having at least one side anchored to the top shielding, the electrical conductive film being pressed by the elastomer and partially covering the trench so as to be electrically connected with the high-frequency device with a predetermined contact pressure.

14. The electronic equipment as claimed in claim 13, wherein the top shielding comprises at least one of aluminum, aluminum-magnesium alloy or other conductive materials.

15. The electronic equipment as claimed in claim 13, wherein the elastomer is a foamed sponge or PU foam.

16. The electronic equipment as claimed in claim 13, wherein the electrical conductive film is in indirect contact with the high-frequency device via a grounding device.

17. The electronic equipment as claimed in claim 16, wherein the grounding device further comprises a grounding port, which is connected to a grounding terminal, so that RF noise from high-frequency devices is directed from the grounding port to the grounding terminal.

18. The electronic equipment as claimed in claim 13, wherein the electrical conductive film comprises a high conductivity material.

19. The electronic equipment as claimed in claim 18, wherein the high conductivity material comprises copper.

20. The electronic equipment as claimed in claim 13, wherein the predetermined contact pressure between the electrical conductive film and the high-frequency device is greater than about 100 mg/cm².
